(19) United States
(12) Patent Application Publication
(10) Pub. No.: US 2008/0173890 A1
(43) Pub. Date: Jul. 24, 2008

(54) Multidirectional light-emitting diode

(76) Inventor: Wen-Kung Sung, Taipei City (TW)

Correspondence Address: TROXELL LAW OFFICE PLLC, SUITE 1404, 5205 LEESBURG PIKE, FALLS CHURCH, VA, 22041, US

(21) Appl. No.: 11/655,291

(22) Filed: Jan. 19, 2007

(51) Int. Cl. H01L 33/00

(52) U.S. Cl. 257/99; 257/E33.001

(57) ABSTRACT

A multidirectional light-emitting diode comprises a frame, at least one light-emitting chip, at least two connection wires, and a transparent material for covering above-mentioned components, wherein the light-emitting chip is connected with the frame via the connection wires, and the light-emitting chip, the connection wires, and partial portion of the frame are covered by the transparent material so as to suspend the light-emitting chip for generating 360-degree omni-directional light beams.

### FIELD OF THE INVENTION

The present invention relates to a multidirectional light-emitting diode capable of generating 360-degree omni-directional light beams.

### BACKGROUND OF THE INVENTION

The light-emitting diodes provide the advantages of low power consumption and long lifetime. As a result, the light-emitting diodes are usually adopted as indicator lights of electronic products.

As shown in FIG. 7, a conventional light-emitting diode has a base A on which a recessed cup A1 is formed, wherein a chip B is attached to the base A inside the recessed cup A1. In addition, the chip B is connected with another frame D via a connection wire C. Finally, the base A, the chip B, the connection wire C, and the frame D are integrated into a unity by a transparent layer E, which is formed by an injection-molding method, so as to complete the light-emitting diode.

However, if the above-mentioned conventional light-emitting diode is electrified, the light beams emitted from the lateral and bottom surfaces of the chip will be blocked and reflected by the recessed cup. Accordingly, the conventional light-emitting diode can only generate the forward light. In other words, the light beams emitted from the chip can not be observed from the backside or the lateral surfaces of the light-emitting diode.

Moreover, as disclosed by Japanese Laid-Open Patent Application Nos. 5-327026 and 2000-223752 (shown in FIG. 8 and FIG. 9), the chip can be electrically connected with a printed circuit board by SMT (surface mount technology). If the printed circuit board is electrified, the light beams can be emitted outward from five surfaces (front, rear, left, right, and top surfaces) of the chip, but the light beams still can not be emitted outward from the bottom surface of the chip.

In view of the foregoing description, the motive of the present invention is to provide the general public with a multidirectional light-emitting diode so that the light beams emitted from the light-emitting diode can be observed at any angle.

### SUMMARY OF THE INVENTION

A major object of the present invention is to provide a multidirectional light-emitting diode capable of emitting 360-degree light beams so that the light beams emitted from the light-emitting diode can be observed at any angle.

In order to achieve the above-mentioned object, a multidirectional light-emitting diode is comprised of a frame, at least one light-emitting chip, at least two connection wires, and a transparent material for covering above-mentioned components, wherein the light-emitting chip is connected with the frame via the connection wires, and the light-emitting chip, the connection wires, and partial portion of the frame are covered by the transparent material so as to suspend the light-emitting chip for generating 360-degree omni-directional light beams.

The aforementioned object and other advantages of the present invention will be readily clarified in the description of the preferred embodiments and the enclosed drawings of the present invention.

### BRIEF DESCRIPTION OF THE DRAWINGS

FIG. 1 is a cross-sectional view showing a first preferred embodiment of the present invention.

FIG. 2 is an elevational view showing the light-emitting chip of the present invention.

FIG. 3 is a cross-sectional view showing the usage status of the first preferred embodiment of the present invention.

FIG. 4 is a top view showing the usage status of the first preferred embodiment of the present invention.

FIG. 5 is an elevational view showing a second preferred embodiment of the present invention.

FIG. 6 is a cross-sectional diagram of FIG. 5.

FIG. 7 is a cross-sectional view showing a conventional light-emitting diode.

FIG. 8 is a cross-sectional view showing a conventional light-emitting diode disclosed by Japanese Laid-Open Patent Application No. 5-327026.

FIG. 9 is a cross-sectional view showing a conventional light-emitting diode disclosed by Japanese Laid-Open Patent Application No. 2000-223752.

### DETAILED DESCRIPTION OF THE PREFERRED EMBODIMENT

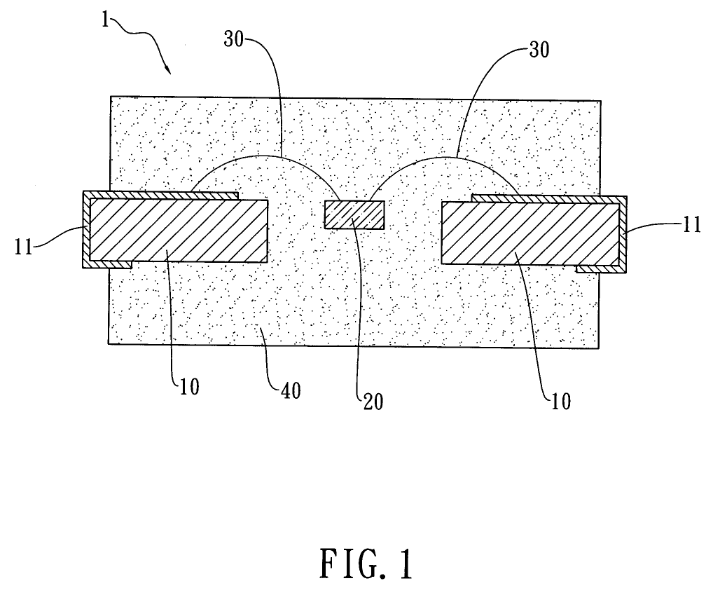

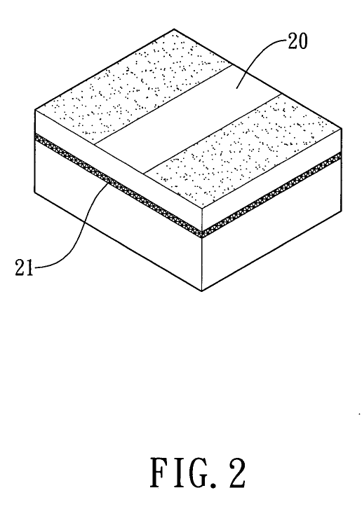

Referring to FIG. 1, a first preferred embodiment of the present invention is shown. A light-emitting diode 1 comprises two conducting frames, a light-emitting chip 20, two connection wires 30, and a transparent material 40. These two conducting frames have identical structure so the description below is focused on only one of them. Each of the frames is formed by covering a small-scale circuit board 10 with a layer of conducting material 11, wherein the conducting material 11 is selected from a group consisting of gold, silver, tin, chromium, nickel, and alloy. These two frames are opposite to each other, and the chip 20 is located between these two frames. The positive and negative electrodes of the chip 20 must be located on the same side. As shown in FIG. 2, a light-emitting layer 21 of the chip 20 is mounted on the middle, and a bottom substrate of the chip 20 must be transparent. The chip 20 is connected to the respective conducting materials 11 of these two frames via these two connection wires 30, respectively. Finally, the chip 20, these two connection wires 30, and partial portions of these two frames (i.e., the positions connected to the connection wires 30) are covered with the transparent material 40 so as to suspend the chip 20 so as to complete the assemblage of the present invention.

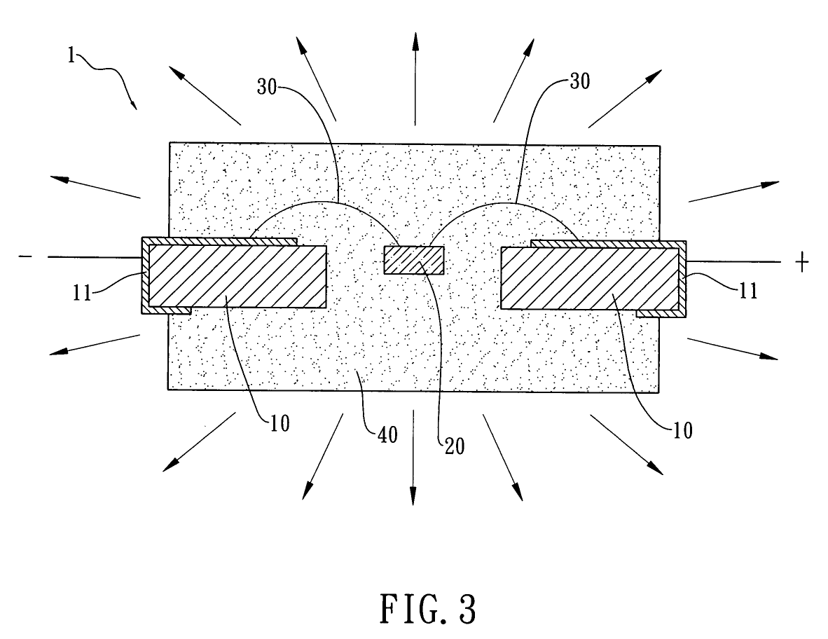

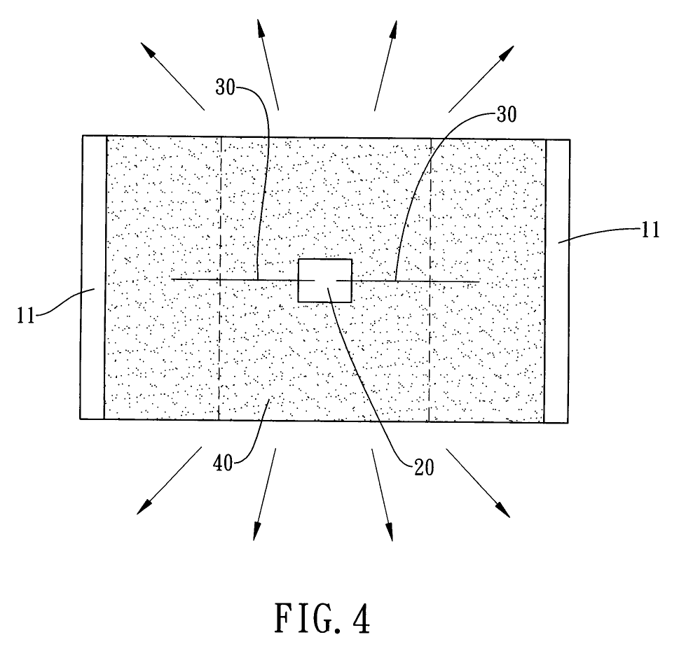

When in use, the frames of the light-emitting diode 1 of the present invention are connected with positive potential and negative potential by their respective sides so that the chip 20 can be excited by the electric current to emit light beams. Because the chip 20 is suspended and no obstructer is mounted on the periphery of the chip 20 to block the light beams of the chip 20, the chip 20 can generate 360-degree light beams. As shown in both FIG. 3 and FIG. 4, the light beams emitted from the chip 20 can be observed easily at any angle. Accordingly, the light-emitting diode 1 can achieve the same effect as the general tungsten lamp, thereby further replacing the tungsten lamp.

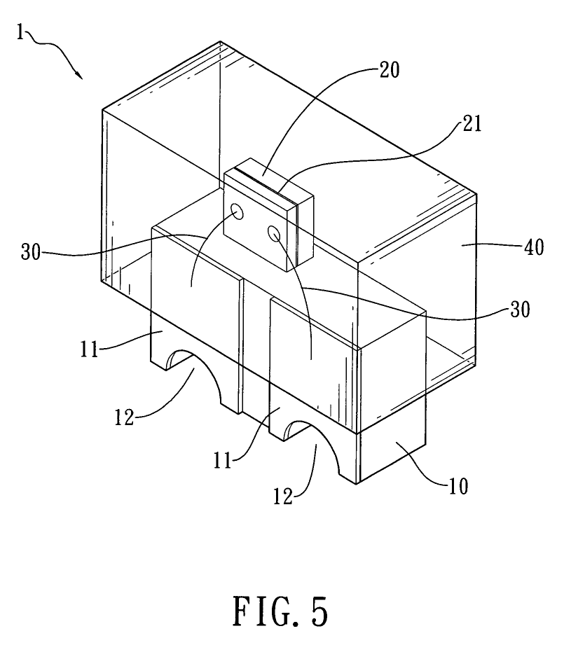

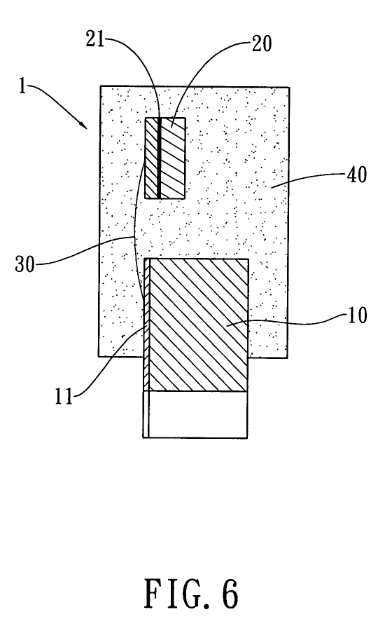

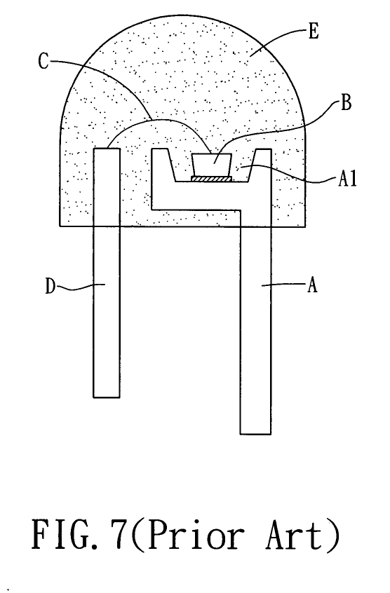

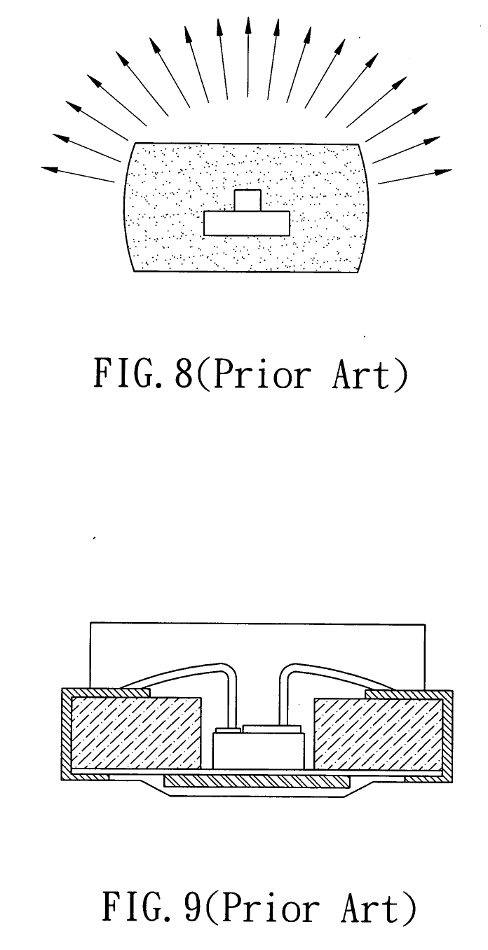

Referring to FIG. 5 and FIG. 6, a second preferred embodiment of the present invention is shown. A frame, which is composed of a circuit board 10, is provided. The circuit board 10 has through holes 12 on both left and right sides of the bottom surface so that tin solders can be weld thereinto for direct electrical connection of the circuit board 10 by SMT (surface mount technology). The front surface of the circuit board 10 is covered with two conducting materials 11 on opposite sides. These two conducting materials 11 are insulated from each other. In addition, the chip 20 is located upside down and suspended above the circuit board 10. At this moment, the electrodes of the chip 20 and the conducting materials 11 are mounted on the same side. The chip 20 is connected with these two conducting materials 11 via two connection wires 30, respectively. Finally, the chip 20, the connection wires 30, and partial upper portion of the frame are covered with a transparent material 40 so as to complete the assemblage of the present invention.

In accordance with the foregoing description, the present invention has the following practical advantages:

1. The chip can generate omni-directional light since the chip is suspended and no obstructer, which is able to block the light beams of the chip, is mounted on the periphery of the chip.

2. The light-emitting chip is covered with the transparent material directly to overcome the drawback of the conventional structure, which bonds the chip to the substrate or the recessed cup by the adhesive and which can only generate the forward light.

3. The chip is suspended so the light beams emitted from the chip can be observed easily at any angle.

4. The chip is not mounted on the frame by any adhesive so the light beams emitted from the chip will not be blocked by the adhesive.

In summary, a multidirectional light-emitting diode of the present invention indeed achieves the anticipated purposes. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A multidirectional light-emitting diode comprising:
at least one frame;
at least one light-emitting chip having a positive electrode and a negative electrode on a top surface and a transparent bottom substrate;
at least two connection wires for connecting said at least one light-emitting chip with said at least one frame; and
a transparent material for covering said at least one light-emitting chip, said at least two connection wires, and said at least one frame so as to suspend said at least one light-emitting chip for generating 360-degree omni-directional light beams.

2. A multidirectional light-emitting diode of claim 1, wherein there are two frames, and said two frames are formed by covering two oppositely located circuit boards with two conducting materials, respectively.

3. A multidirectional light-emitting diode of claim 2, wherein said two conducting materials are selected from a group consisting of gold, silver, tin, chromium, nickel, and alloy.

4. A multidirectional light-emitting diode of claim 1, wherein said at least one frame is formed by covering two opposite sides of a front surface of a circuit board with two conducting materials, respectively, and said two conducting materials are insulated from each other.

5. A multidirectional light-emitting diode of claim 4, wherein said two conducting materials are selected from a group consisting of gold, silver, tin, chromium, nickel, and alloy.

6. A multidirectional light-emitting diode of claim 1, wherein said at least one light-emitting chip and said at least two connection wires are fully covered by said transparent material and said at least one frame is partially covered by said transparent material.
